(19) United States
(12) Patent Application Publication
(10) Pub. No.: US 2026/0235485 A1
(43) Pub. Date: Aug. 13, 2026

(54) SURFACE INSPECTION METHOD AND STANDARD SUBSTRATE FOR SURFACE INSPECTION

(71) Applicant: TOCALO CO., LTD., Kobe-shi, Hyogo (JP)

(72) Inventors: Akira ISHIHAMA, Kobe-shi, Hyogo (JP); Kensuke TAGUCHI, Akashi-shi, Hyogo (JP); Michinori TANAKA, Akashi-shi, Hyogo (JP); Asuka SUZUKI, Funabashi-shi,, Chiba (JP)

(21) Appl. No.: 19/471,878

(22) PCT Filed: Mar. 27, 2024
(86) PCT No.: PCT/JP2024/012174

§ 371 Date: Oct. 2, 2025

(30) Foreign Application Priority Data
Apr. 7, 2023 (JP) 2023-062825

(51) Int. Cl. G01N 15/0205; H10P 50/24; H10P 74/20

(52) U.S. Cl. CPC G01N 15/0211; H10P 50/242; H10P 74/203

(57) ABSTRACT

The present disclosure is a surface inspection method that includes a step of etching a substrate having fine particles adhered thereto, and forming pillars directly below the fine particles, and a step of irradiating the substrate having the formed pillars with laser light, and inspecting a surface of the substrate.

### CROSS-REFERENCE TO RELATED APPLICATIONS

This application is a U.S. national phase application filed under 35 U.S.C. § 371 of International Application Number PCT/JP2024/012174 filed Mar. 27, 2024, designating the United States, which claims priority from Japanese Application Number 2023-062825, filed Apr. 7, 2023.

### FIELD OF THE INVENTION

The present disclosure relates to a surface inspection method and a standard substrate, and particularly to a surface inspection method including irradiating a surface of an object to be inspected with laser light, and a standard substrate used in surface inspection.

### BACKGROUND OF THE INVENTION

In recent years, as semiconductors become, for example, highly integrated, there is a need for reducing fine particles generated from chamber components or protective films formed on the chamber components in a plasma processing apparatus during a plasma processing step for semiconductor substrates. Analysis and investigation of the generated fine particles require detection of the fine particles that adhere onto the substrates.

There are very fine particles, measuring a few tens of nanometers in diameter, among the fine particles that adhere onto the substrates. However, since a general-purpose surface inspection device that uses scattered laser light has a detection sensitivity of about 50 nm, it is difficult to detect the fine particles having such sizes.

While as a method for detecting the fine particles, a method for detecting using a high-performance surface inspection device having a detection sensitivity of a few more than 10 nm is considered, such high-performance surface inspection device is correspondingly very expensive.

Furthermore, as high integration in semiconductors continues to advance in coming years, it is expected that the presence of fine particles having even smaller diameters, for example, diameters of 10 nm or less, will be a problem. In such cases, it will be difficult to detect the fine particles even when a high-performance surface inspection device is used. Therefore, there is a need for a method for detecting fine particles that are difficult to detect in current surface inspection devices.

The following methods have been known previously as methods for detecting minute objects and defects. For example, Patent Literature 1 describes a method including forming sidewalls on column-shaped residues formed after an anisotropic etching process, and performing quantitative optical evaluation. Patent Literatures 2 and 3 then describe methods including evaluating etching residues that are exposed at crystal defects in a substrate or a certain layer, using anisotropic etching with a high selectivity ratio.

### CITATION LIST

### Patent Literature

[Patent Literature 1] Japanese Laid-Open Patent Publication No. H04-279042.

[Patent Literature 2] Japanese Laid-Open Patent Publication No. 2000-058509.

[Patent Literature 3] Japanese Laid-Open Patent Publication No. 2016-058424.

[Patent Literature 4] Japanese Laid-Open Patent Publication No. 2009-025221.

### SUMMARY OF INVENTION

On the other hand, the methods described in Patent Literatures 1 to 3 are not intended to detect fine particles themselves that adhere onto a substrate.

The present disclosure is made in view of the foregoing problem, and its purpose is to provide a surface inspection method capable of detecting fine particles on a substrate.

A surface inspection method according to the present disclosure includes the following steps (a) and (b).

The step (a) is a step of etching a substrate having a fine particle adhered thereto, and thereby forming a pillar directly below the fine particle.

The step (b) is a step of irradiating the substrate having the formed pillar with laser light, and thereby inspecting a surface of the substrate.

Examples of more detailed features of the surface inspection method according to the present disclosure, which may be cited, include the following (1) to (5).
(1) The fine particle has a diameter of 10 nm or less.
(2) The substrate material is single crystal silicon.
(3) The fine particle has an etching rate that is one-fifth or less as compared with the etching rate of single crystal silicon.
(4) The etching is performed until the height of the pillar is five times or more the height of the fine particle.
(5) The fine particle consists of a compound containing one or more of rare earth elements, Al, and W, or from a mixture thereof.

Furthermore, the surface inspection method according to the present disclosure preferably further includes the following feature (6) and step (c).
(6) The step of inspecting the surface in the step (b) is a step of measuring a laser scattering intensity of the pillar after the etching.

The step (c) is a step of comparing a laser scattering intensity of a standard pillar prepared in advance with the laser scattering intensity of the pillar after the etching, and thereby calculating a diameter of the fine particle.

A standard substrate according to the present disclosure is a standard substrate for use in surface inspection that includes measuring laser scattering intensity, the standard substrate including one or more standard pillars having aspect ratios from 0.5 to 10 and diameters of 500 nm or less, or 100 nm or less.

The present disclosure can provide a surface inspection method capable of detecting fine particles that adhere onto a substrate.

### BRIEF DESCRIPTION OF DRAWINGS

FIGS. 1A to 1C are cross-sectional views of steps for sequentially explaining steps of a surface inspection method according to one embodiment of the present disclosure.

FIG. 2 is a cross-sectional view of a step for explaining step (a) of a surface inspection method according to another embodiment of the present disclosure.

FIG. 3 is a perspective view of a standard substrate according to one embodiment of the present disclosure.

FIGS. 4A to 4C are plan views of standard substrates according to one embodiment of the present disclosure.

### DETAILED DESCRIPTION

One embodiment of a surface inspection method according to the present disclosure is described below with reference to the drawings.

The surface inspection method in one embodiment includes the following steps (a) and (b):

step (a) of etching a substrate having fine particles adhered thereto, and thereby forming pillars directly below the fine particles; and

step (b) of irradiating the substrate having the formed pillars with laser light, and thereby inspecting the surface.

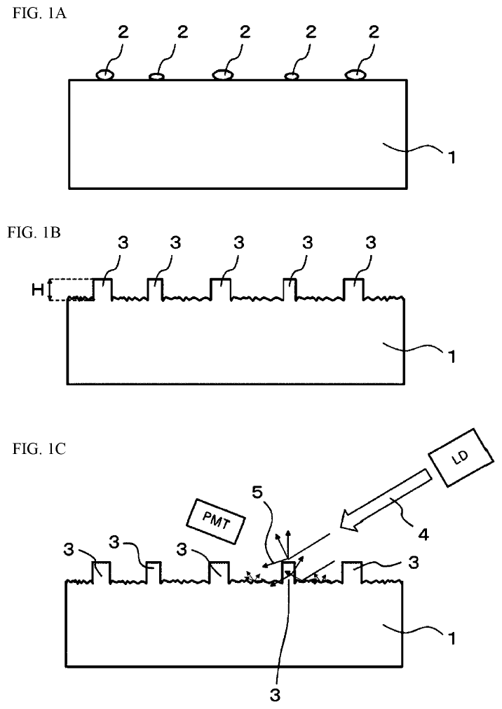

Steps (a) and (b) are described below in detail with reference to FIGS. 1A to 1C. As shown in FIGS. 1A and 1B, in step (a), a substrate 1 having fine particles 2 adhered thereto is etched to form pillars 3 directly below the fine particles 2. In this etching, the fine particles 2 substantially function as masks to etch a surface of the substrate 1, so that the pillars 3 having height H and formed from part of the substrate 1 are formed in areas where the fine particles 2 are present. Although not shown in FIG. 1B, small portions of the fine particles etched by etching remain on the pillars 3.

A material of the substrate 1 used in step (a) is, for example, silicon or SiO₂. The silicon may be single crystal silicon. A substrate made of silicon can be, for example, a commercially available silicon substrate for semiconductors.

A type of the fine particle 2 can include, for example, a compound containing metal elements. The fine particle 2 suitable for the surface inspection method in the embodiment can include a compound containing one or more of rare earth elements, aluminum (Al), and tungsten (W). Such fine particle 2 has an etching rate that is much lower as compared with the etching rate of silicon. Thus, particularly when a silicon substrate is used as the substrate, the pillars 3 having the height H suitable for surface inspection using scattered laser light can be formed directly below the fine particles 2, resulting in excellent accuracy of the surface inspection that uses irradiation with laser light 4.

In the specification, the fine particle 2 has a diameter defined as a diameter of a circle that corresponds to a planer shape of the fine particle 2 when viewed from above. The diameter of the fine particle 2 that is detected is not particularly limited, and for example, the fine particles 2 having diameters from 1 nm to 500 nm can be included. In the surface inspection method in the embodiment, even when the fine particles 2 have diameters from 1 nm to 10 nm, which are diameters difficult to detect by a general-purpose surface inspection device, the presence of the fine particles 2 can be detected through forming directly below the fine particles 2 the pillars 3 having a size detectable by a general-purpose surface inspection device.

The fine particle 2 can include, for example, fine particles 2 generated from portions of metal components, or portions of protective films formed on the metal components, in a processing device for the substrate 1. Types of the metal and the protective films are not particularly limited. The fine particle 2 suitable for the surface inspection method in the embodiment can include fine particles 2 generated from portions of chamber components or portions of protective films formed on the chamber components in a plasma processing apparatus. Such fine particles 2 include particles having a very small diameter which are difficult to detect by a general-purpose surface inspection device. The surface inspection method in the embodiment can detect the presence of the fine particles 2 through forming directly below the fine particles 2 the pillars 3 having a size detectable by a general-purpose surface inspection device, and is thus suitable for surface inspection for the fine particles 2 having the diameter as described above.

The etching in step (a) can be etching commonly used in the semiconductor field, and can include, for example, dry etching, and particularly, anisotropic etching is preferable. When anisotropic etching is performed in step (a), the pillars 3 directly below the fine particles 2 are less susceptible to etching, so that the pillars 3 can be prevented from disappearing even when the etching is performed for an extended period of time. Conditions for anisotropic etching can be appropriately selected as suitable conditions from among conditions in which, for example, an F-based reaction gas (CF₄, C₂F₆, SF₆, NF₃, ClF₃) or a Cl-based reaction gas (Cl₂, BCl₃, CF₃C₁, CCl₄, SiCl₄) is mixed with an additive gas (for example, O₂, Ar, N₂, H₂) as necessary, and high frequency power is from 50 to 5000 W, and bias power is from 10 to 1000 W.

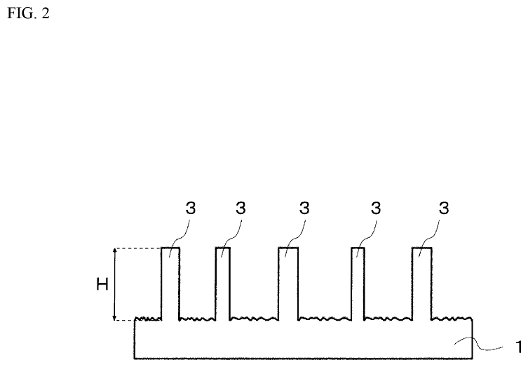

As shown in FIG. 2, the etching in step (a) is preferably performed until the height H of the pillar 3 is 5 times or more the height of the fine particle 2, more preferably 10 times or more, and even more preferably 50 times or more. Thereby, even when the fine particles 2 have diameters from 1 nm to 10 nm, which are diameters difficult to detect by a general-purpose surface inspection device, the height H of the pillars formed directly below can be as great as a level detectable by a general-purpose surface inspection device, so that the presence of the fine particles 2 having the diameters as described above can be detected. In the specification, the height H of the pillar is a distance from a lower end to an upper end of the formed pillar 3, and the height of the fine particle 2 is a distance from a lower end to an upper end of the fine particle 2. The height H of the pillars 3 in FIG. 2 is preferably 5 times or more the diameter of the fine particles 2 as described above, but is shown to be about 4 times for the sake of convenience in illustration.

The etching rate of the fine particle 2 in step (a) is then preferably ⅕ or less, more preferably 1/10 or less, and even more preferably 1/50 or less, as compared with the etching rate of single crystal silicon. In the case of such fine particles 2, when the material of the substrate 1 is single crystal silicon and the fine particles 2 have diameters from 1 nm to 10 nm, which are diameters difficult to detect by a general-purpose surface inspection device, the height H of the pillars 3 can be as great as a level detectable by the general-purpose surface inspection device, as shown in FIG. 2, by the time the fine particles 2 having the diameters as described above disappear due to etching. Thereby, the presence of the fine particles 2 having the diameters as described above can be detected.

Further, the etching rate of the fine particle 2 in step (a) is preferably equal to or less than the etching rate of SiO₂. In the case of such etching rate that is equal to or less than the etching rate of SiO₂, the pillars 3 having the height H suitable for surface inspection using scattered laser light can be formed directly below the fine particles 2, particularly when a silicon substrate is used as the substrate. This enables excellent accuracy of the surface inspection that uses irradiation with laser light 4. The etching rate of the fine particle 2 in step (a) is more preferably ½ or less, and even more preferably 1/10 or less, as compared with the etching rate of SiO₂. In this way, as shown in FIG. 2, the pillars 3 having the height H suitable for surface inspection using scattered laser light can be formed directly below the fine particles 2, resulting in excellent accuracy of the surface inspection that uses measurement of scattered laser light 5.

The pillar 3 formed in step (a) has a shape that can include, for example, a rectangular prism shape, and a cylindrical shape. The pillar 3 formed in step (a) has a diameter that is not particularly limited as long as the pillar 3 can be detected by measurement of scattered laser light 5. In the specification, the diameter of the pillar 3 is defined as a diameter of a circle that corresponds to a planer shape of the pillar 3 when viewed from above. As shown in FIG. 2, the height H of the pillar 3 formed in step (a) is preferably 5 times or more the height of the fine particle 2, more preferably 10 times or more, and even more preferably 50 times or more. Thereby, even when the fine particles 2 have diameters from 1 nm to 10 nm, which are diameters difficult to detect by a general-purpose surface inspection device, the height H of the pillars 3 formed directly below the fine particles 2 can be as great as a level detectable by a general-purpose surface inspection device, so that the presence of the fine particles 2 having the diameters as described above can be detected.

As shown in FIG. 1C, in step (b), the substrate 1 having the formed pillars 3 is irradiated with laser light 4 to inspect the surface. More particularly, the substrate 1 having the formed pillars 3 is irradiated with laser light 4 that is generated by a semiconductor laser diode (LD), and scattered laser light 5 produced when the laser light 4 strikes the pillars 3 is received by a photomultiplier tube (PMT) to measure an intensity of the scattered laser light 5 (also called “laser scattering intensity”) from the pillars 3. This makes it possible to detect the pillars 3 based on the measured laser scattering intensity, and to detect the presence of the fine particles 2 based on the presence of the pillars 3.

The measurement of the laser scattering intensity in step (b) can be carried out, for example, by using a general-purpose surface inspection device that uses scattered laser light.

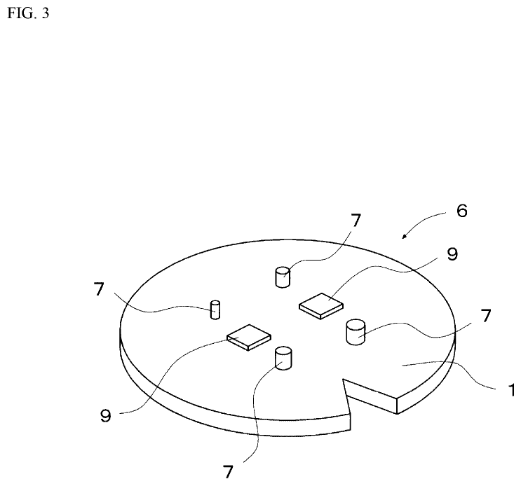

A standard substrate according to one embodiment of the present disclosure is described below. FIG. 3 is a perspective view showing an example of the standard substrate.

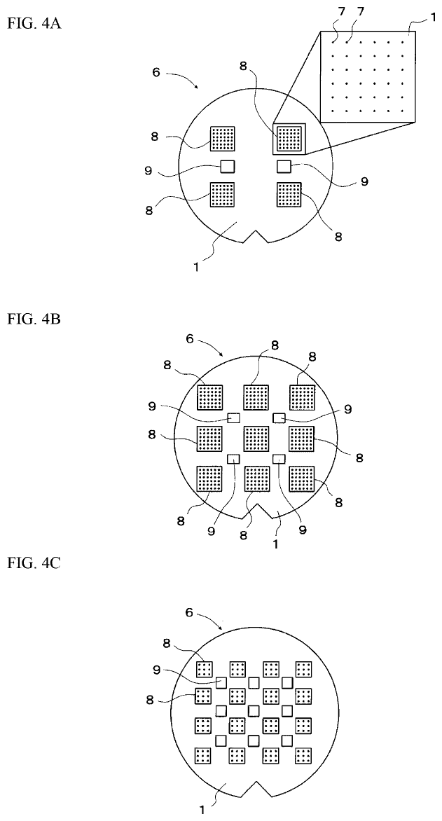

A standard substrate 6 in one embodiment is used to calculate the diameters of the fine particles 2. The standard substrate 6 shown in FIG. 3 is made of the same material as the substrate 1 used in step (a), and a plurality of standard pillars 7 have heights that are all equal, and diameters that are each different. The standard substrate 6 may be configured to only have one standard pillar 7. When the standard substrate 6 includes the plurality of standard pillars 7, the diameters of the plurality of standard pillars 7 do not all need to be different, and a standard pillar group 8 including a plurality of standard pillars 7 that have the same diameter may be included (see FIGS. 4A to 4C). The standard pillars 7 are preferably produced under etching conditions equal to those used in step (a). Thereby, the height of the plurality of standard pillars 7 is equal to the height H of the pillars 3 formed in step (a). Thus, when the laser scattering intensity of the plurality of standard pillars 7 is compared with the laser scattering intensity of the pillars 3 formed in step (a), the diameters of the fine particles 2 can be calculated. For comparing the laser scattering intensity of the plurality of standard pillars 7 with the laser scattering intensity of the pillars 3 formed in step (a), a calibration curve based on the laser scattering intensity of the plurality of standard pillars 7 may be generated in advance. The calibration curve is not particularly limited, and can include, for example, a calibration curve where the vertical axis represents the laser scattering intensity and the horizontal axis represents the diameters of the standard pillars 7. Also, the standard substrate 6 is preferably cleaned for use before generating the calibration curve. However, the embodiment is not limited to this example.

The use of such standard substrate 6 facilitates calculating the diameters of the fine particles 2 from the measured laser scattering intensity. The standard pillars 7 preferably have aspect ratios from 0.5 to 100. The diameters of the standard pillars 7 differ depending on the diameters of the fine particles 2 to be measured, and may be, for example, from 1 nm to 100 nm, or from 1 nm to 500 nm. The aspect ratio is calculated by dividing the height of the standard pillar by the diameter of the standard pillar, the diameter of the standard pillar being determined by the definition as described above, and the height of the standard pillar being a distance from a lower end to an upper end of the standard pillar.

FIGS. 4A to 4C are plan views showing other examples of the standard substrate. As shown in FIGS. 4A to 4C, the standard substrate 6 in one embodiment includes an arrangement in which the standard pillars are densely packed in a certain area, i.e., a standard pillar group 8. In such cases, the standard pillar group 8 has, for example, a density from 1 pieces/cm² to 1000 pieces/cm² . The distance between the standard pillars 7 is preferably 100 μm or more. When the distance between the standard pillars 7 is 100 μm or more, the distance between the standard pillars 7 is greater than the spot diameter of laser light from a commonly used laser irradiation device, and each of the standard pillars 7 can be irradiated with the laser light, so that the laser scattering intensity of each of the standard pillars 7 can be obtained more accurately. An example of the upper limit is, for example, 1000 μm. In the enlarged view of the standard pillar group 8 in the standard substrate 6 in FIG. 4A, the standard pillars 7 are shown as dots for the sake of convenience in illustration. In this regard, the distance between the standard pillars 7 is, for example, 100 times or more the diameter of the standard pillar 7, but is shown as being shorter than such distance for the sake of convenience in illustration. In this respect, this also applies to FIGS. 4B and 4C described below.

Also, the plurality of standard pillars 7 densely packed in the standard pillar group 8 may all have the same diameter. In an example of a method for using such standard substrate 6, for example, the plurality of standard pillars 7 densely packed in the standard pillar group 8 and having the same diameter (the diameter is X) are each irradiated with laser light, and the laser scattering intensity of the standard pillars 7 is obtained as a cumulative distribution. Then, a most frequent value of the laser scattering intensity of the standard pillars 7 having the diameter X is calculated from the obtained cumulative distribution, and thereby, the laser scattering intensity of the standard pillars 7 having the diameter X can be obtained more accurately.

The standard substrate 6 preferably includes a positioning mark 9. The positioning mark 9 is a mark provided near the area where the standard pillars 7 are densely packed, and is provided to easily identify positions of the standard pillars 7 and the standard pillar groups 8 when high-magnification optical microscopy is performed, for example. The number of standard pillar groups 8 is not particularly limited and may be appropriately selected according to the size of the substrate 1. For example, it may be four as shown in FIG. 4A, nine as shown in FIG. 4B, or 16 as shown in FIG. 4C.

Conventional methods for identifying the size of a defect, such as a fine particle, include, for example, a method in which a standard particle having a known particle size is adhered onto a substrate, and a characteristic quantity of the standard particle (such as sum or maximum of signal intensity) is compared with a characteristic quantity of the defect to calculate the size of the defect, as described in Patent Literature 4. However, in such conventional standard substrate, the individual standard particles are small and thus, the standard particles may aggregate with each other, which may cause fluctuations in measured values of laser scattering intensity and cause problems in reproducibility. In this regard, measured values of laser scattering intensity obtained by a surface inspection device may vary depending on the time of measurement due to the effects of aging deterioration on the surface inspection device, for example. For this reason, it is preferable to re-obtain the laser scattering intensity of the standard substrate at regular intervals. In this respect, when the standard substrate is left for a certain period of time and dust in the atmosphere adheres to the standard substrate, the laser scattering intensity cannot be accurately measured. It is therefore necessary to remove the dust adhered onto the standard substrate to reuse the standard substrate. In the case of the conventional standard substrate, even when attempting to clean the dust adhered onto the standard substrate, it is not possible to separate and wash away only the dust. It was therefore necessary to refabricate a standard substrate every time a surface inspection test was performed. In the standard substrate 6 in the embodiment, the substrate 1 and the standard pillars 7 are configured to be formed as one piece. In this way, even if dust or the like adheres onto the standard substrate 6 after the standard substrate 6 is left for a certain period of time, a cleaning process used in a common semiconductor fabrication process can be carried out to clean only the dust. Therefore, a standard laser scattering intensity exhibiting excellent reproducibility can be obtained, and there is no need to refabricate a standard substrate 6 every time a surface inspection test is performed.

The standard substrate 6 can be appropriately fabricated from, for example, a silicon substrate, for example, using processing techniques commonly used in the semiconductor field. Although not shown, the standard substrate 6 is fabricated, for example, by preparing a substrate including the same material as that of the substrate used in step (a), and etching the substrate in the state where a plurality of masks having different diameters are placed on the substrate. The standard substrate 6 is preferably fabricated under etching conditions equal to those used in step (a). Thus, when the standard substrate is fabricated from the same material as that of the substrate used in step (a) and under the etching conditions equal to those used in step (a), the height of the standard pillars 7 can be equal to the height H of the pillars 3 formed in step (a).

Also, in the embodiment, as step (c), the laser scattering intensity of the standard pillars 7 can be compared with the laser scattering intensity of the pillars 3 formed in step (a) to calculate the diameters of the fine particles 2. Specifically, the standard substrate 6 including the plurality of standard pillars 7 is prepared and the laser scattering intensities of the standard pillars are measured. In so doing, the standard substrate 6 is made of the same material as that of the substrate 1 used in step (a), the height H of the plurality of standard pillars 7 is equal to the height H of the pillars 3 formed directly below the fine particles, and the diameters of the plurality of standard pillars 7 are each different. Then, after measuring the laser scattering intensities of the pillars 3 formed directly below the fine particles 2, the laser scattering intensities of the plurality of standard pillars 7 having magnitudes equal to the laser scattering intensities of the pillars 3 are identified from among the laser scattering intensities of the plurality of standard pillars 7. When pillars have the same material and equal height, the laser scattering intensity is determined by the diameter of each pillar.

Therefore, by identifying the laser scattering intensities of the plurality of standard pillars 7 having magnitudes equal to the laser scattering intensities of the pillars 3 from among the laser scattering intensities of the plurality of standard pillars 7, the diameters of the pillars 3 can be identified. Since the diameters of the pillars 3 correspond to the diameters of the fine particles 2 directly above the pillars 3, and the diameters of the pillars 3 are calculated using the steps as described above, the diameters of the fine particles 2 can be calculated. The diameter of the standard pillar 7 is defined in the same way as the definition for the diameter of the pillar 3 as described above, that is, it is defined as a diameter of a circle that corresponds to a planer shape of the standard pillar 7 when viewed from above.

In the embodiment, the method for calculating the diameters of fine particles 2 is described by using the standard substrate 6 in which the height of the standard pillars 7 is equal to the height H of the pillars 3 formed in step (a); however, the embodiment is not limited to this configuration.

The present disclosure provides a surface inspection method capable of detecting fine particles adhered onto a substrate, and can therefore be widely utilized in the semiconductor field and other industrial fields.

### Description of Reference Characters

1 Substrate
2 Fine particle
3 Pillar
4 Laser light
5 Scattered laser light
6 Standard substrate
7 Standard pillar
8 Standard pillar group
9 Positioning mark
H Height of pillar

What is claimed is:

1. A surface inspection method comprising:
a step of etching a substrate having a fine particle adhered thereto, and thereby forming a pillar directly below the fine particle, and
a step of irradiating the substrate having the formed pillar with laser light, and thereby inspecting a surface of the substrate.

2. The method according to claim 1, wherein the fine particle has a diameter of 10 nm or less.

3. The method according to claim 1, wherein the substrate material is single crystal silicon.

4. The method according to claim 3, wherein the fine particle has an etching rate that is one-fifth or less as compared with the etching rate of single crystal silicon.

5. The method according to claim 1, wherein the etching is performed until the height of the pillar is five times or more the height of the fine particle.

6. The method according to claim 1, wherein the fine particle consists of a compound containing one or more of rare earth elements, Al, and W, or from a mixture thereof.

7. The method according to claim 1, wherein the step of inspecting the surface is a step of measuring a laser scattering intensity of the pillar after the etching, and
the method further includes a step of comparing a laser scattering intensity of a standard pillar prepared in advance with the laser scattering intensity of the pillar after the etching, and thereby calculating a diameter of the fine particle.

8. A standard substrate for use in surface inspection that includes measuring laser scattering intensity, the standard substrate comprising one or more standard pillars having aspect ratios from 0.5 to 10 and diameters of 500 nm or less.
